(19) United States
(12) Patent Application Publication
(10) Pub. No.: US 2025/0311301 A1
(43) Pub. Date: Oct. 2, 2025

(54) GATE-ALL-AROUND DEVICES AND METHODS FOR MANUFACTURING SAME

(71) Applicant: Taiwan Semiconductor Manufacturing Company, Ltd., Hsin-Chu (TW)

(72) Inventors: Chung-I Yang, Hsinchu City (TW); Bo-Yu Lai, Taipei City (TW); Che-Lun Chang, Hsinchu (TW); Wei-Yang Lee, Taipei City (TW); Kuo-Cheng Chiang, Zhubei City (TW)

(21) Appl. No.: 18/785,364

(22) Filed: Jul. 26, 2024

Related U.S. Application Data
(60) Provisional application No. 63/571,801, filed on Mar. 29, 2024.

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 64/018; H10D 64/021; H10D 84/0128; H10D 84/013; H10D 84/0135; H10D 84/038; H10D 84/83

(57) ABSTRACT

A method of the present disclosure includes forming a structure including multiple channel members vertically stacked above a substrate, forming a source/drain feature abutting the channel members, after the forming of the source/drain feature depositing a dielectric material layer wrapping around the channel members with voids remaining between adjacent ones of the channel members after the deposition of the dielectric material layer, selectively removing a center portion of the dielectric material layer to release the channel members, and forming a metal gate structure wrapping around the channel members. A side portion of the dielectric material layer interposes the metal gate structure and the source/drain feature.

### PRIORITY DATA

This application claims priority to U.S. Provisional Patent Application No. 63/571,801, filed on Mar. 29, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. As GAA devices continue to scale, challenges have arisen. For example, in a GAA process flow, formation of inner spacers can be an important process to reduce capacitance and prevent leakage between gate stacks and source/drain regions. However, the existing structures and fabrication technologies have various issues, which includes causing poor epitaxial growth and crystalline dislocation in source/drain regions. Therefore, although existing structure and fabrication techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2, 3, 4, 5A, 5B, 6, 7A, 7B, 8A, 8B, 8C, 9A, 9B, 10A, 10B, 11A, 11B, 12A, 12B, 12C, 13A, 13B, 14A, 14B, 15A, 15B, 16A, and 16B illustrate fragmentary cross-sectional views of a work-in-progress (WIP) structure during a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

The present disclosure is generally related to multi-gate transistors and fabrication methods, and more particularly to inner spacer formation during fabricating gate-all-around (GAA) transistors. Inner spacers provide isolation between a gate structure and adjacent source/drain regions inside a GAA transistor. As used herein, source/drain region(s) may refer to a region that provides a source and/or a drain for one or multiple devices. It may also refer to a source or a drain individually or collectively of one or multiple devices, dependent upon the context.

Multi-gate transistors include those transistors whose gate structures are formed on at least two-sides of a channel region. These multi-gate devices may include a p-type field effect transistor (PFET) or an n-type field effect transistor (NFET). Specific examples presented herein are embodiments of a type of multi-gate transistor referred to as a gate-all-around (GAA) transistor. A GAA transistor includes its gate structure, or portion thereof, formed on all four sides of a channel (e.g., wrapping around a channel). Devices presented herein also include embodiments that have a channel disposed in one or more nanostructures, such as nanosheets, nanowires, bar-shaped nanostructures, and/or other suitable configurations. The nanostructures are also referred to as channel members. Presented herein are embodiments of devices that may have one or more channel members (e.g., nanosheets) associated with a single, contiguous gate structure. However, one of ordinary skill would recognize that the teaching can apply to a single channel member (e.g., a single nanosheet) or any number of channel members. One of ordinary skill may recognize other examples of semiconductor devices that may benefit from aspects of the present disclosure.

A GAA transistor includes inner spacers and gate spacers (also termed as outer spacers), among others. Inner spacers are typically formed prior to the source/drain features. In an exemplary GAA fabrication flow, after making source/drain trenches, a space for inner spacers is made by partially removing sacrificial layers that are alternatively arranged with channel layers. Then, inner spacers are formed in the space by dielectric material deposition and proper etching process. However, the inner spacers introduce dielectric surfaces interleaving with semiconductor surfaces from the channel layers on sidewalls of the source/drain trenches. Consequently, subsequent epitaxial growth of source/drain features is limited to those discontinued semiconductor surfaces exposed on the sidewalls of the source/drain trenches. The portions of the source/drain features separately grown from those discontinued semiconductor surfaces would later merge after reaching certain height. However, such an epitaxial growing process may easily lead to poor epitaxial quality (e.g., with voids underneath) and source/drain feature dislocation in the source/drain regions. An object of the present disclosure is to devise an inner spacer formation method so as to improve quality of source/drain features epitaxially grown in the source/drain regions, while maintaining integrity of accurate dimensions and positions of the inner spacers.

In an example process of the present disclosure for forming a GAA transistor, a fin-shaped structure with channel layers and sacrificial layers is formed over a substrate. After formation of a dummy gate stack over a channel region of the fin-shaped structure, gate sidewall spacers are formed over the dummy gate stack. Source/drain regions of the fin-shaped structure are recessed. Source/drain features are then formed over the source/drain recesses. After removal of the dummy gate stack, the sacrificial layers are selectively removed to release the channel layers as channel members. A dielectric layer is then deposited in space between adjacent ones of the channel members. The dielectric layer is then etched back and partially recessed to form inner spacers between the channel members. A gate structure is then formed to wrap around each of the channel members.

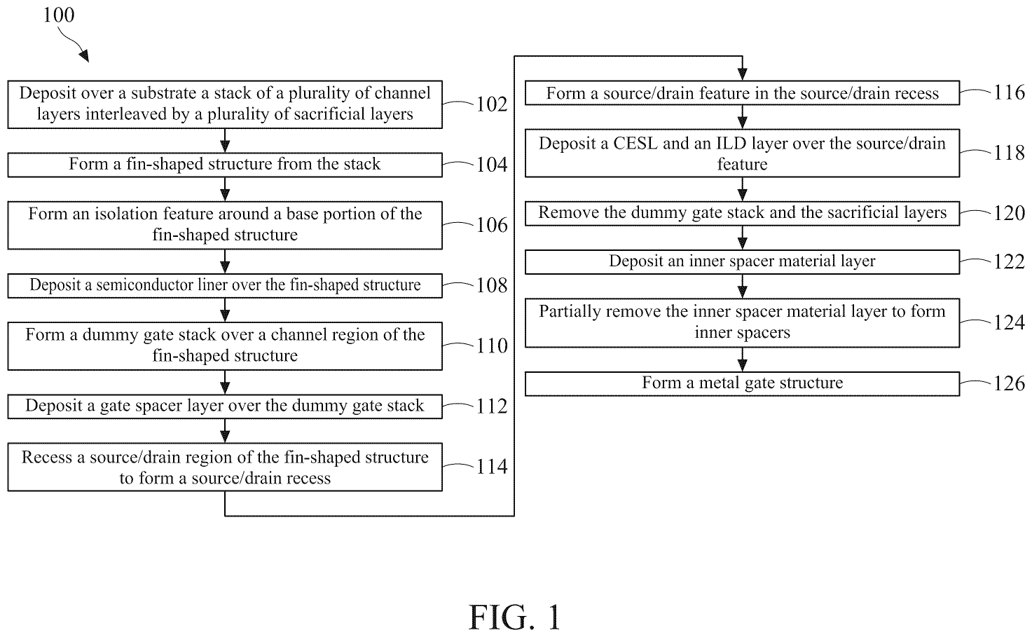

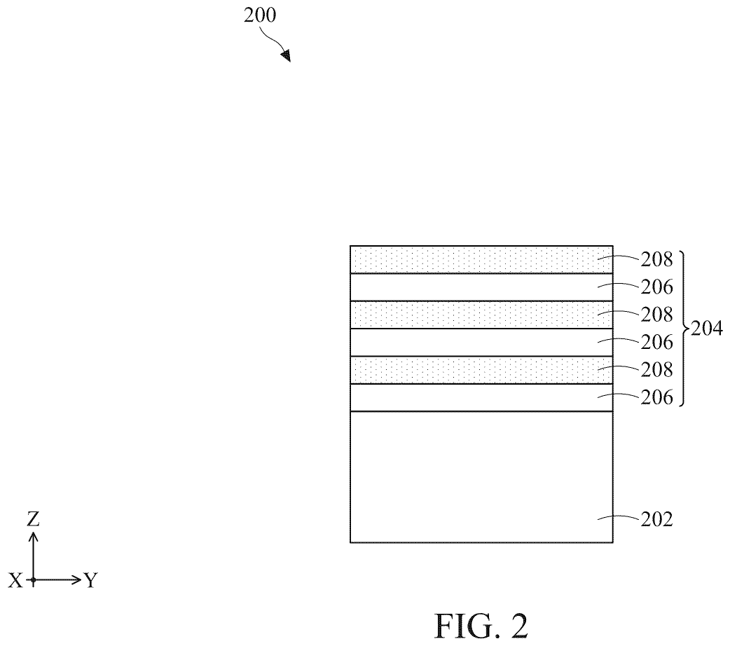

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-16B, which are fragmentary cross-sectional views of a WIP structure 200 at different stages of fabrication according to embodiments of the method 100 in FIG. 1. Because the WIP structure 200 will be fabricated into a semiconductor structure or a semiconductor device, the WIP structure 200 is also referred to herein as a semiconductor structure 200 or a semiconductor device 200. For avoidance of doubts, the X, Y and Z directions in FIGS. 2-16B are perpendicular to one another. Throughout the present disclosure, unless expressly described otherwise, like reference numerals denote like features or steps.

Referring to FIGS. 1 and 2, method 100 includes a block 102 where a stack 204 of alternating semiconductor layers is formed over the semiconductor device 200. As shown in FIG. 2, the semiconductor device 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the performance needs for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

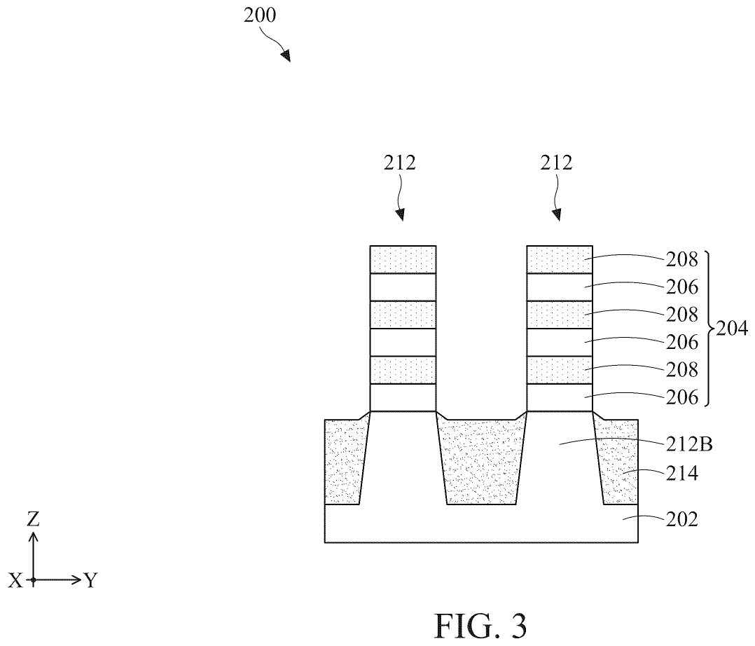

Referring to FIGS. 1 and 3, method 100 includes a block 104 where a fin-shaped structure 212 is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etching process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. As shown in FIG. 3, the etching process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 extends vertically along the Z direction and lengthwise along the X direction. As shown in FIG. 3, the fin-shaped structure 212 includes a fin-shaped base 212B patterned from the substrate 202 and the patterned stack 204 disposed directly over the fin-shaped base 212B. In some instances, a width of the fin-shaped structures 212 measured along the Y direction may be between about 3 nm and about 20 nm.

Still referring to FIGS. 1 and 3, method 100 includes a block 106 where an isolation feature 214 is formed around the fin-shaped base 212B of the fin-shaped structures 212. In some embodiments represented in FIG. 3, the isolation feature 214 is disposed on sidewalls of the fin-shaped base 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the fin-shaped base 212B is embedded or buried in the isolation feature 214.

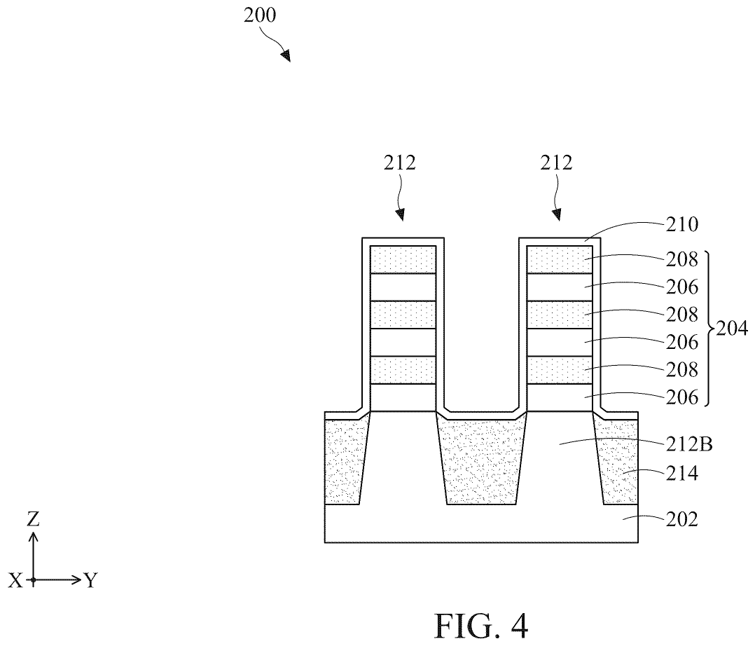

Referring to FIGS. 1 and 4, method 100 includes a block 108 where a semiconductor liner 210 is deposited over the fin-shaped structure 212. After the formation of the isolation feature 214, a semiconductor liner 210 may be deposited over the semiconductor device 200, including over the isolation feature 214, over a top surface of the fin-shaped structure 212, and along sidewalls of the fin-shaped structure 212. The semiconductor liner 210 functions to protect the sidewalls of the sacrificial layers 206 as they can sustain undesirable damages during the fabrication processes. In some embodiments, the semiconductor liner 210 may include silicon (Si). In some implementations, the semiconductor liner 210 may be deposited using PVD, CVD, or atomic layer deposition (ALD).

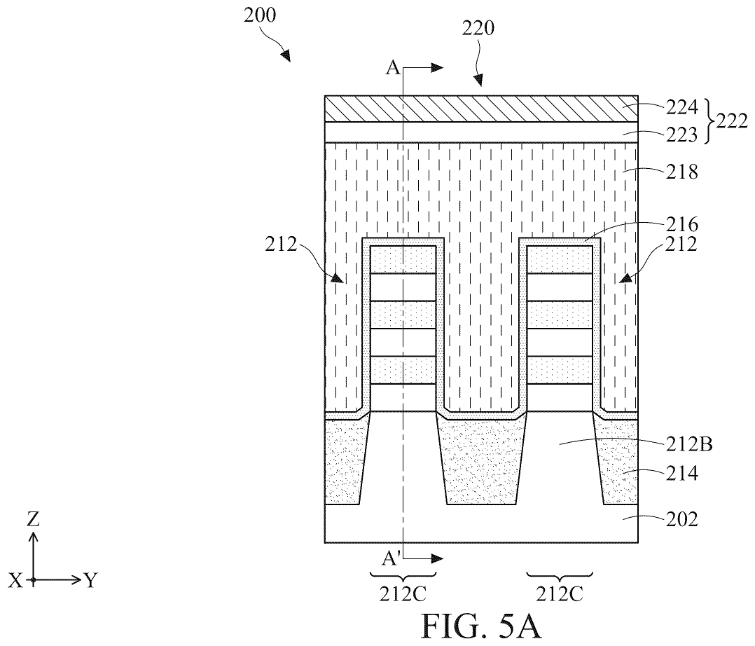

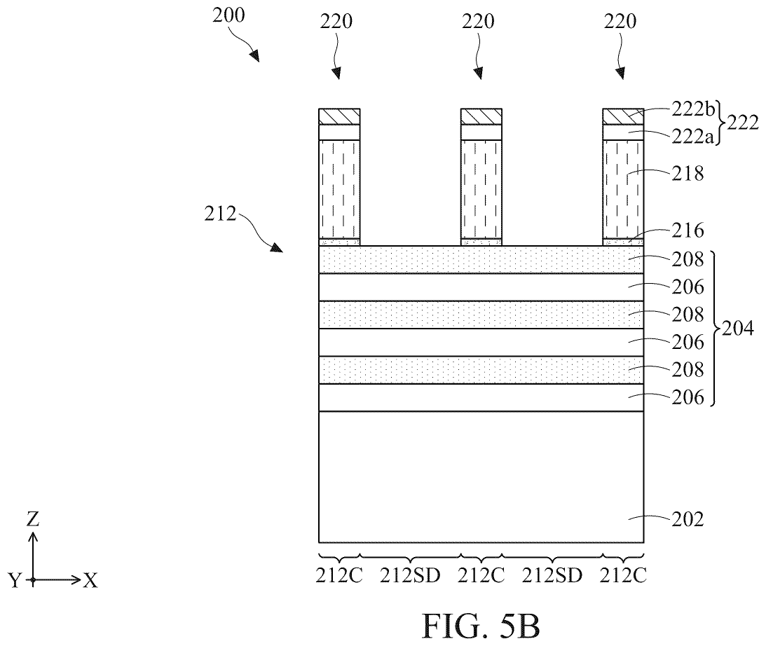

Referring to FIGS. 1 and 5A-B, method 100 includes a block 110 where a dummy gate stack 220 is formed over a channel region 212C of the fin-shaped structure 212. The dummy gate stack 220 serves as a placeholder to undergo various processes and is to be removed and replaced by a functional gate structure. Other processes and configuration are possible. FIG. 5B is a cross-sectional view along the A-A line in FIG. 5A. In some embodiments as illustrated in FIG. 5B, multiple dummy gate stacks 220 are formed over the fin-shaped structure 212, and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 5B, the channel region 212C is disposed between two source/drain regions 212SD along the X direction.

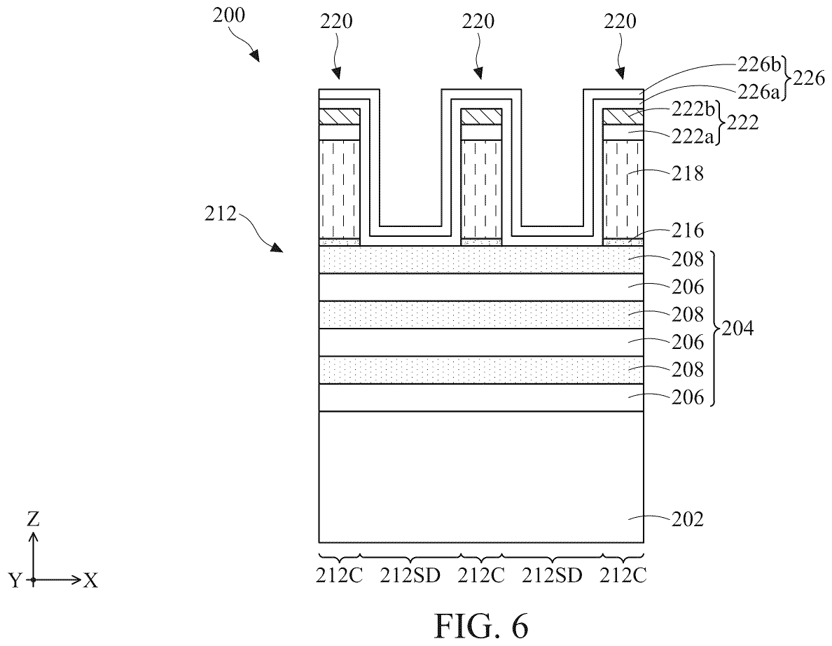

The formation of the dummy gate stack 220 may include deposition of layers in the dummy gate stack 220 and patterning of these layers. Referring to FIG. 5A, a dummy dielectric layer 216, a dummy electrode layer 218, and a gate-top hard mask layer 222 may be blanketly deposited over the semiconductor device 200. The dummy dielectric layer 216 may be formed on the fin-shaped structure 212 using a chemical vapor deposition (CVD) process, an ALD process, an oxygen plasma oxidation process, or other suitable processes. In the depicted embodiment, the dummy dielectric layer 216 is formed using an oxygen plasma oxidation process that substantially oxidizes the semiconductor liner 210 to form the dummy dielectric layer 216. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 6. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218, and the dummy dielectric layer 216. In some embodiments, the etching process may include dry etching (e.g., RIE etching), wet etching, and/or other etching methods. In some embodiments, the gate-top hard mask layer 222 may include a silicon oxide layer 222a and a silicon nitride layer 222b over the silicon oxide layer 222a. As shown in FIG. 6, the dummy gate stack 220 is patterned such that it is only disposed over the channel region 212C, not disposed over the source/drain region 212SD.

Referring to FIGS. 1 and 6, method 100 includes a block 112 where a gate spacer layer 226 is deposited over the semiconductor device 200, including over the dummy gate stack 220. In some embodiments, the gate spacer layer 226 is deposited conformally over the semiconductor device 200, including over top surfaces and sidewalls of the dummy gate stack 220. The term “conformally” may be used herein for case of description of a layer having substantially uniform thickness over various regions. The gate spacer layer 226 may be deposited over the dummy gate stack 220 using processes such as, a CVD process, a subatmospheric CVD (SACVD) process, an ALD process, or other suitable process. The gate spacer layer 226 may be a single layer or a multi-layer. The at least one layer in the gate spacer layer 226 may include silicon carbonitride, silicon oxycarbide, silicon oxycarbonitride, or silicon nitride. In some embodiments, the gate spacer layer 226 may include an inner layer 226a of silicon oxide and an outer layer 226b of silicon nitride over the inner layer 226a.

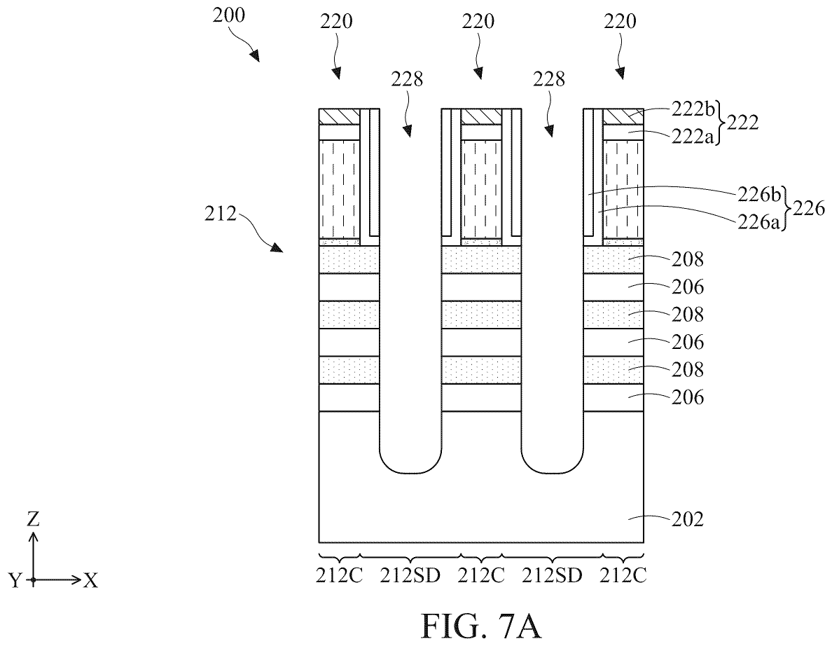

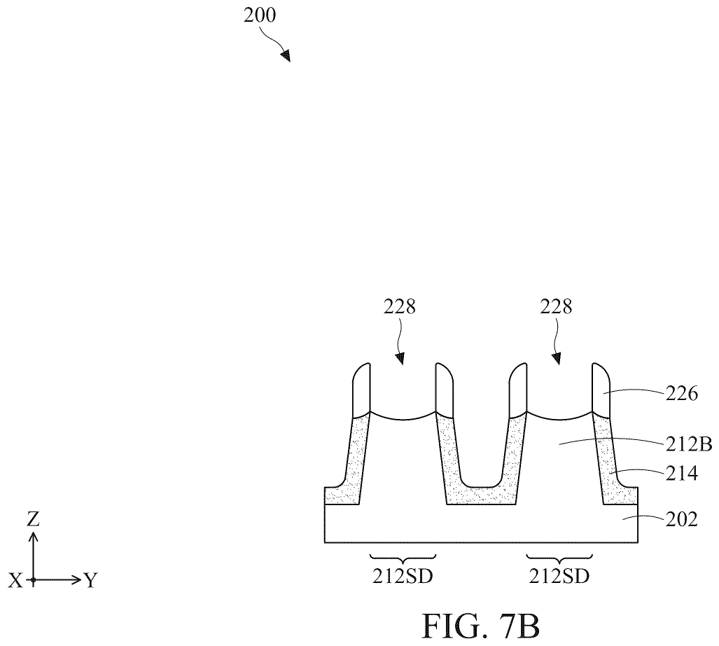

Referring to FIGS. 1 and 7A-B, method 100 includes a block 114 where source/drain regions 212SD of the fin-shaped structure 212 are anisotropically recessed to form source/drain trenches 228. The anisotropic etch may include a dry etch or a suitable etching process that etches the source/drain regions 212SD and a portion of the substrate 202. The resulting source/drain trenches 228 extend vertically through the depth of the stack 204 and partially into the substrate 202. An example dry etching process for block 114 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BC₁₃), a bromine-containing gas (e.g., HBr and/or CHBr₃), an iodine-containing gas, other suitable gases and/or plasmas, and/or combinations thereof. As illustrated in FIG. 7B, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202. Reference is made to FIG. 7B, which includes a fragmentary cross-sectional view across two adjacent source/drain regions 212SD. As shown in FIG. 7B, over the source/drain regions 212SD, the majority of the fin-shaped structure 212 is etched away and a top surface of the fin-shaped base 212B is exposed in the source/drain region 212SD. Because the gate spacer layer 226 etches at a slower rate than the fin-shaped structure 212, the gate spacer layer 226 in the source/drain region 212SD rises above the top surface of the fin-shaped base 212B. The portions of the gate spacer layer 226 remain on the sidewalls of the dummy gate stack 220 (as shown in FIG. 7A) are referred to as the gate spacers, while the other portions of the gate spacer layer 226 remain on the top surface of the fin-shape base 212B (as shown in FIG. 7B) are also referred to as the fin spacers.

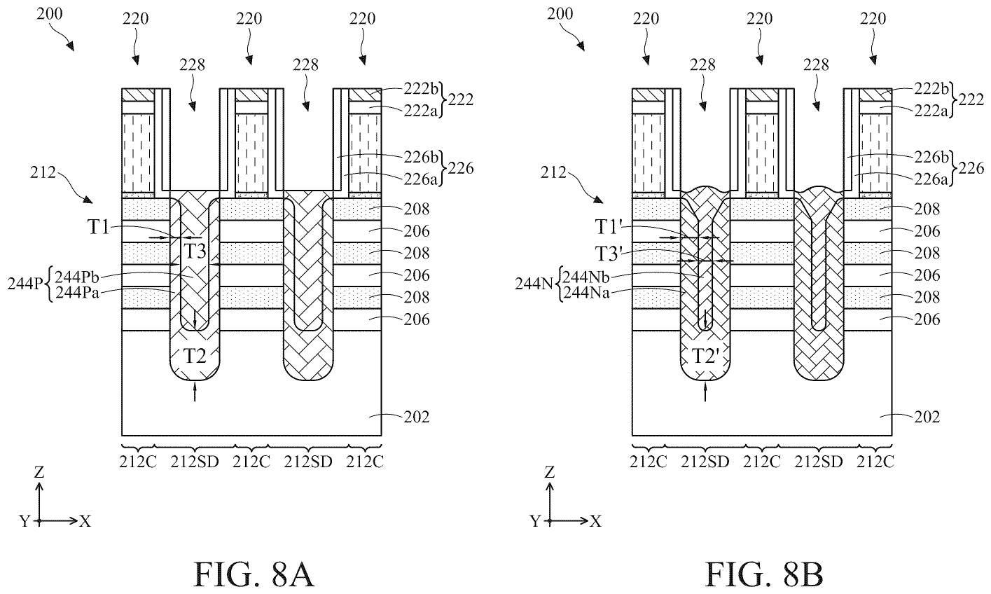

Referring to FIGS. 1 and 8A-C, method 100 includes a block 116 where source/drain features 244 are formed over the source/drain region 212SD. The source/drain features 244 include n-type source/drain features 244N formed in an NFET region, as shown in FIG. 8A, and p-type source/drain features 244P formed in a PFET region, as shown in FIG. 8B. FIG. 8C is a fragmentary cross-sectional view across two adjacent source/drain regions 212SD, in which one includes a p-type source/drain feature 244P and another includes an n-type source/drain feature 244N.

The p-type source/drain feature 244P may include silicon germanium (SiGe) and a p-type dopant, such as boron (B), gallium (Ga), or a combination thereof. In the depicted embodiment as shown in FIG. 8A, the p-type source/drain feature 244P may include multiple layers. For example, the p-type source/drain feature 244P may include a lightly doped epitaxial layer 244Pa over the sidewall and bottom surfaces of the source/drain trench 228 and a heavily doped epitaxial layer 244Pb over the lightly doped epitaxial layer 244Pa. The lightly doped epitaxial layer 244Pa includes a smaller dopant concentration (e.g., B %) and a smaller germanium concentration (e.g., Ge %) in atomic percentage than in the heavily doped epitaxial layer 244Pb to reduce crystalline dislocation and other crystalline defects. In some embodiments, G % in the lightly doped epitaxial layer 244Pa is between about 10% and about 20%, and G % in the heavily doped epitaxial layer 244Pb is between about 30% and about 60%. Notably, G % in the lightly doped epitaxial layer 244Pa is also different from G % in the sacrificial layers 206, which allows selective etching to remove the sacrificial layers 206 in a subsequent process with the lightly doped epitaxial layer 244Pa as an etch stop layer. For example, G % in the sacrificial layers 206 may range between about 20% and 30%, which is higher than that of the lightly doped epitaxial layer 244Pa but lower than that of the heavily doped epitaxial layer 244Pb.

Each of the epitaxial layers 244Pa and 244Pb may be formed using vapor-phase epitaxy (VPE), ultra-high vacuum CVD (UHV-CVD), or molecular beam epitaxy (MBE). Doping of the epitaxial layers 244Pa and 244Pb may be achieved with in-situ doping. Since the sidewall and bottom surfaces of the source/drain trench 228 comprise continuous semiconductor surfaces as from the end portions of the sacrificial layers 206, the end portions of the channel layers 208, and the top surface of the substrate 202, the lightly doped epitaxial layer 244Pa is a continuous layer. In the depicted embodiment, the lightly doped epitaxial layer 244Pa has two vertical portions and a horizontal portion in forming a U-shape. Each vertical portion of the lightly doped epitaxial layer 244Pa conformally covers the sidewall of the source/drain trench 228 with a substantially uniform thickness T1. The outer sidewall of the lightly doped epitaxial layer 244Pa facing the fin-shaped structure 212 and the inner sidewall of the lightly doped epitaxial layer 244Pa facing the source/drain trench 228 are both substantially flat and vertical in the depicted embodiment. The horizontal portion of the lightly doped epitaxial layer 244Pa has a thickness T2 that is larger than T1 (i.e., T2>T1), which is due to a faster crystal growth rate from the top surface of the substrate 202. The heavily doped epitaxial layer 244Pb includes a lower portion surrounded by the lightly doped epitaxial layer 244Pa and an upper portion capping the lightly doped epitaxial layer 244Pa. The lower portion of the heavily doped epitaxial layer 244Pb has a thickness T3 that is larger than T1 (i.e., T3>T1), such that the heavily doped epitaxial layer 244Pb may account for a majority of the volume of the p-type source/drain feature 244P to reduce contact resistance. Depending on the epitaxial growth time of the lightly doped epitaxial layer 244Pa, the thickness T3 may be smaller than T2 (i.e., T3<T2), as depicted in FIG. 8A, or larger than T2 (i.e., T3>T2) in an alternative embodiment.

The n-type source/drain feature 244N may include silicon (Si) and an n-type dopant, such as phosphorus (P), arsenic (As), antimony (Sb), or a combination thereof. In the depicted embodiment as shown in FIG. 8B, the n-type source/drain feature 244N may include multiple layers. For example, the n-type source/drain feature 244N may include a lightly doped epitaxial layer 244Na over the sidewall and bottom surfaces of the source/drain trench 228 and a heavily doped epitaxial layer 244Nb over the lightly doped epitaxial layer 244Na. The lightly doped epitaxial layer 244Na includes a smaller dopant concentration (e.g., P %) in atomic percentage than in the heavily doped epitaxial layer 244Nb to reduce crystalline dislocation and other crystalline defects. In some embodiments, P % in the lightly doped epitaxial layer 244Na is between about 10% and about 20%, and P % in the heavily doped epitaxial layer 244Pb is between about 30% and about 60%.

Each of the epitaxial layers 244Na and 244Nb may be formed using vapor-phase epitaxy (VPE), ultra-high vacuum CVD (UHV-CVD), or molecular beam epitaxy (MBE). Doping of the epitaxial layers 244Na and 244Nb may be achieved with in-situ doping. Since the sidewall and bottom surfaces of the source/drain trench 228 comprise continuous semiconductor surfaces as from the end portions of the sacrificial layers 206, the end portions of the channel layers 208, and the top surface of the substrate 202, the lightly doped epitaxial layer 244Na is a continuous layer. In the depicted embodiment, the lightly doped epitaxial layer 244Na has two vertical portions and a horizontal portion in forming a U-shape. Each vertical portion of the lightly doped epitaxial layer 244Na conformally covers the sidewall of the source/drain trench 228 with a substantially uniform thickness T1′. The outer sidewall of the lightly doped epitaxial layer 244Na facing the fin-shaped structure 212 and the inner sidewall of the lightly doped epitaxial layer 244Na facing the source/drain trench 228 are both substantially flat and vertical in the depicted embodiment. The horizontal portion of the lightly doped epitaxial layer 244Na has a thickness T2′ that is larger than T1′ (i.e., T2′>T1′), which is due to a faster crystal growth rate from the top surface of the substrate 202. The heavily doped epitaxial layer 244Nb includes a lower portion surrounded by the lightly doped epitaxial layer 244Na and an upper portion capping the lightly doped epitaxial layer 244Na. In the depicted embodiment, the lower portion of the heavily doped epitaxial layer 244Nb has a thickness T3′ that is smaller than T1′ and T2′ (i.e., T3′<T1′<T2′), such that the lightly doped epitaxial layer 244Na may account for a majority of the volume of the n-type source/drain feature 244N. Alternatively, depending on the epitaxial growth time of the lightly doped epitaxial layer 244Na, the thickness T3′ may be larger than T1′ but smaller than T2′ (i.e., T1′<T3′<T2′) or larger than both T1′ and T2′ (i.e., T1′<T2′<T3′).

In the depicted embodiment, as the heavily doped epitaxial layer 244Nb has a smaller lower portion than the heavily doped epitaxial layer 244Pb, the upper portion of the heavily doped epitaxial layer 244Nb may protrude out of the top surface of the lightly doped epitaxial layer 244Na than the heavily doped epitaxial layer 244Pb during the epitaxial growth. Stated differently, a topmost portion of the n-type source/drain feature 244N may be higher than a topmost portion of the p-type source/drain feature 244P. Further, the upper portion of the heavily doped epitaxial layer 244Nb may have a wavy top surface compared to the roughly flat top surface of the upper portion of the heavily doped epitaxial layer 244Pb. Stated differently, a top surface of the n-type source/drain feature 244N may have a larger surface roughness than a top surface of the p-type source/drain feature 244P.

In some embodiments represented in FIG. 8C, an n-type source/drain feature 244N may be adjacent a p-type source/drain feature 244P. The n-type source/drain feature 244N may include silicon (Si) and an n-type dopant, such as phosphorus (P), arsenic (As), or antimony (Sb). The p-type source/drain feature 244P may include silicon germanium (SiGe) and a p-type dopant, such as boron (B). The fin spacers 226 may be disposed on lower sidewalls of each of the n-type source/drain feature 244N and the p-type source/drain feature 244P. For case of illustration and description, the n-type source/drain feature 244N and the p-type source/drain feature 244P may be collectively referred to as the source/drain features 244, as in FIG. 8C.

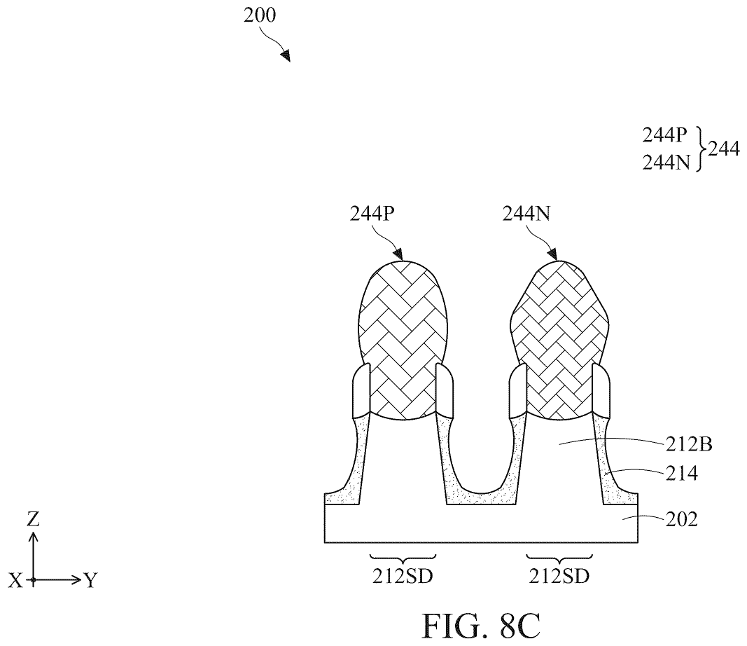

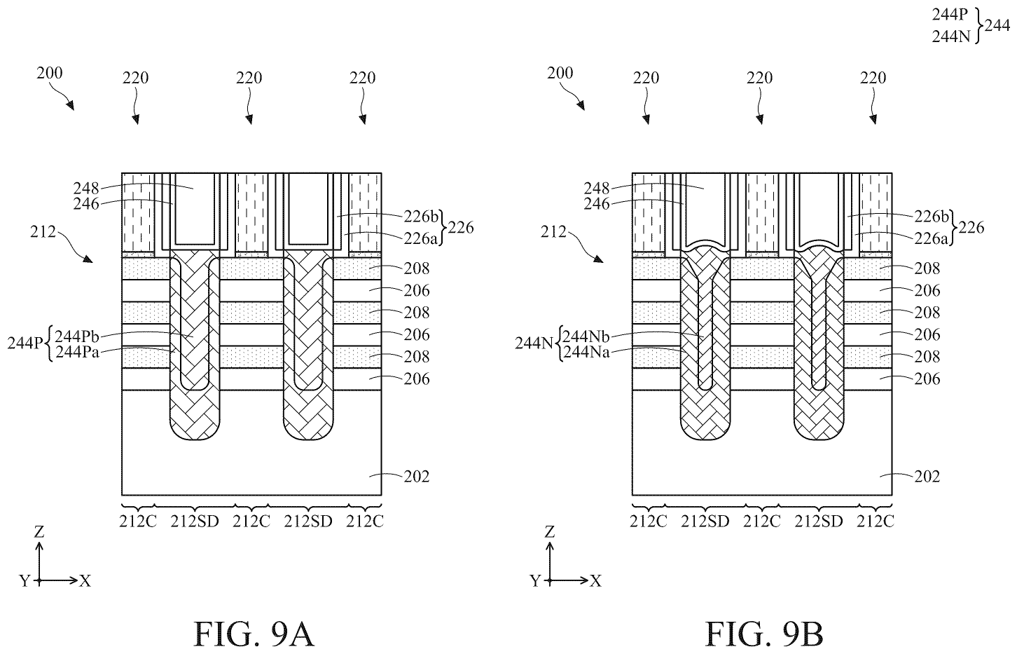

Referring to FIGS. 1 and 9A-B, method 100 includes a block 118 where an inter-layer dielectric (ILD) layer 248 is formed on the source/drain features 244. In some embodiments, a contact etch stop layer (CESL) 246 is also formed prior to forming the ILD layer 248. In some embodiments, the CESL 246 may include silicon nitride or aluminum nitride. In some implementations, the CESL 246 may be deposited using CVD or atomic layer deposition (ALD). The ILD layer 248 is then deposited over the CESL 246. In some embodiments, the ILD layer 248 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be deposited using CVD, flowable CVD (FCVD), spin-on coating, or a suitable deposition technique. After the deposition of the ILD layer 248, the semiconductor device 200 may be planarized by a planarization process to remove the gate-top hard mask layer 222 and expose the dummy gate stack 220. For example, the planarization process may include a chemical mechanical planarization (CMP) process. Exposure of the dummy gate stack 220 allows the removal thereof.

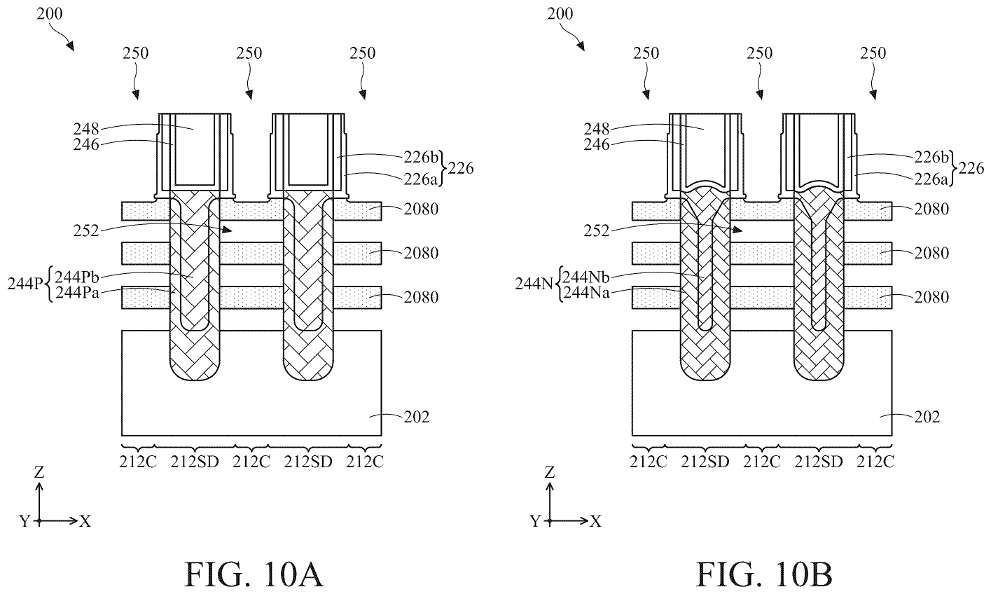

Referring to FIGS. 1 and 10A-B, method 100 includes a block 120 where the dummy gate stack 220 is removed to form a gate trench 250 and the plurality of channel layers 208 are released as channel members 2080. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the formation of the gate trench 250, the sacrificial layers 206 interleaving the channel layers 208 in the channel region 212C are selectively removed. The selective removal of the sacrificial layers 206 releases the channel layers 208 to form channel members 2080. Depending on the design, the channel members 2080 may take form of nanowires, nanorods, nanosheets, or other nanostructures. The selective removal of the sacrificial layers 206 forms spaces 252 between and around adjacent channel members 2080. The selective removal of the sacrificial layers 206 may be implemented by selective dry etch, selective wet etch, or other selective etching processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). The germanium concentration difference between the outer layer of the source/drain features 244 and the sacrificial layers 206 creates etching contrast such that the source/drain features 244 may remain substantially intact during the selective removal of the sacrificial layers 206. Notably, as depicted in FIGS. 10A and 10B, the topmost channel member 2080 may experience some etching loss as being exposed directly in the gate trench 250. This causes the top surface at the center of the topmost channel member 2080 to develop a curvature profile and exposes a portion of the bottom surface of the gate spacer 226.

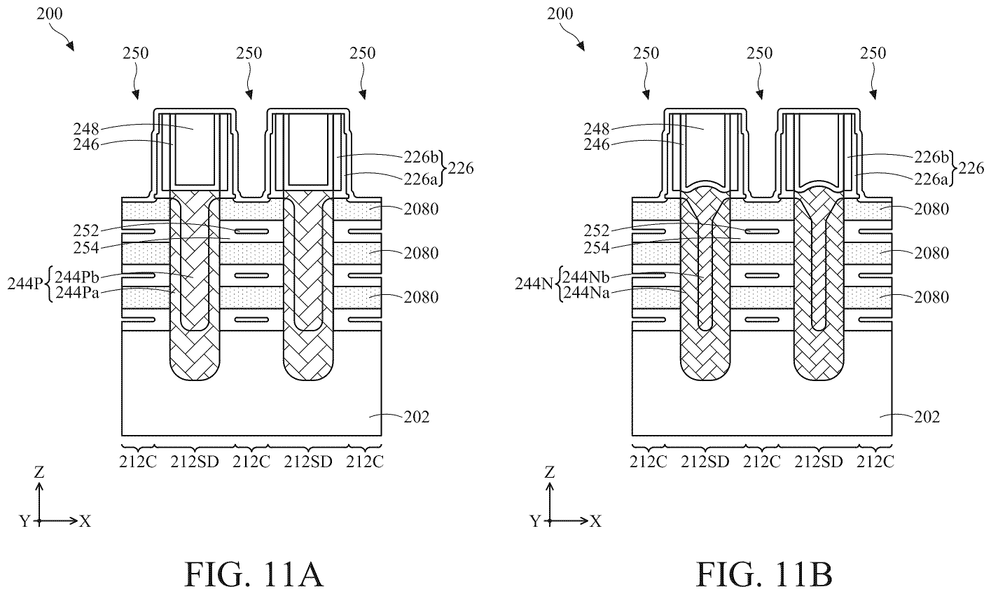

Referring to FIGS. 1 and 11A-B, method 100 includes a block 122 where a dielectric material layer 254 is deposited in the gate trench 250 and in the spaces 252 between and around adjacent channel members 2080. As will be shown in further details below, the dielectric material layer 254 is etched and formed into inner spacers. Therefore, the dielectric material layer 254 is also referred to as the inner spacer material layer 254. The inner spacer material layer 254 may include a dielectric material, such as SiOC, SiOCN, SiCN, and/or other suitable material. In various embodiments, at least the inner layer 226a of the gate spacers 226 and the inner spacer material layer 254 include different material compositions. In one example, the inner layer 226a of the gate spacers 226 includes silicon oxide, while the outer layer 226b of the gate spacers 226 and the inner spacer material layer 254 each include silicon nitride. In another example, the inner layer 226a of the gate spacers 226 includes silicon oxide, the outer layer 226b of the gate spacers 226 includes silicon nitride, and the inner spacer material layer 254 includes silicon oxycarbide. In some embodiments, the inner spacer material layer 254 is deposited in a cyclic deposition and etching (CDE) process. The CDE process may include alternating multiple deposition cycles and multiple etching cycles. In some instances, each of the deposition cycles is followed immediately by an etching cycle. In one example, each of the etch cycles includes use of a fluorine-containing etchant, such as sulfur hexafluoride (SF₆) or nitrogen trifluoride (NF₃). The etching cycles keep removing the dielectric material from the gate spacers 226, preventing the dielectric material from accumulating too quickly and closing the gate trench 250. The etching cycles also allow shank spaces 252 to remain as voids between adjacent channel members 2080. These voids are purposefully retained to enable etchants, applied in subsequent etching processes, to flow into these voids and facilitate the partial removal of the inner spacer material layer 254, thereby forming inner spacers.

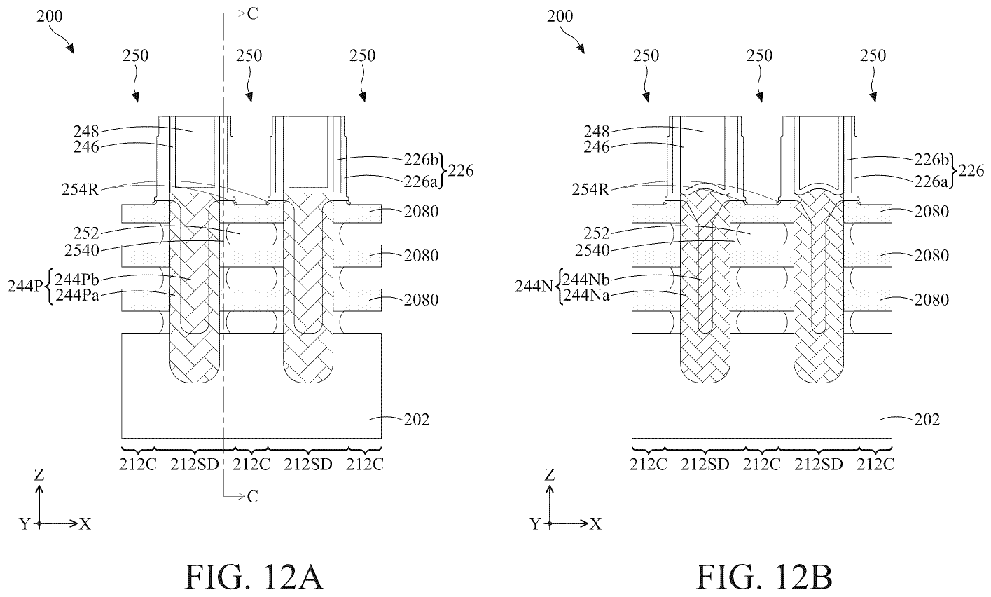

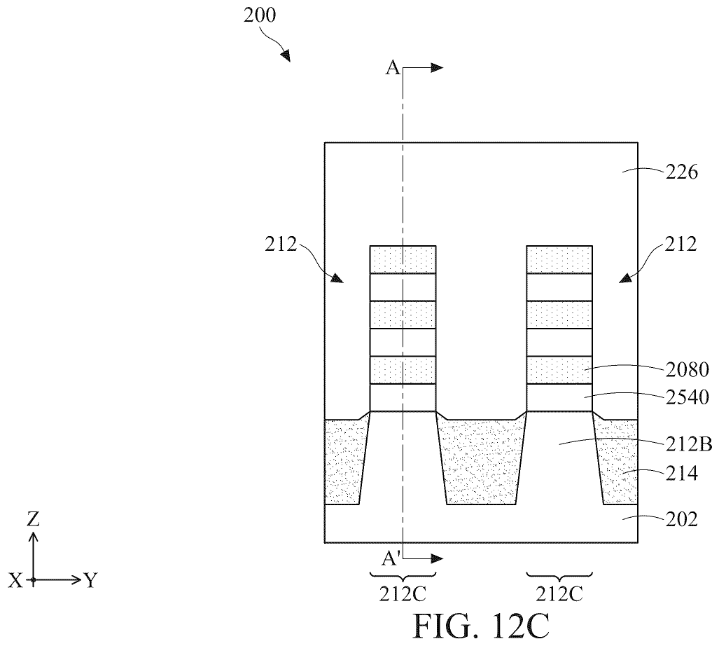

Referring to FIGS. 1 and 12A-C, method 100 includes a block 124 where center portions of the inner spacer material layer 254 are removed from the channel region 212C, while other portions directly under the gate spacers 226 and abutting the source/drain features 244 remain as inner spacers 2540. In some embodiments, the etching process at block 124 includes a cyclic etching process alternating between a surface treatment process and a selective etching process. In the cyclic process, portions of the inner spacer material layer 254 exposed in the channel region 212C repeatedly receive a surface treatment and a subsequent selective etching process to remove the treated surface portion. The cyclic process continues until the inner spacer material layer 254 is completely removed from the channel region 212C, with other portions directly under the gate spacers 226 remaining as inner spacers 2540. In various embodiments, the surface treatment (e.g., an oxidation treatment or a nitridation treatment) is through the gate trench 250, using the gate spacers 226 as a treatment mask, such as shown in FIG. 12C as a cross-sectional view along the C-C line in FIG. 12A in which inner spacers 2540 remain under the gate spacers 226. Still referring to FIGS. 12A and 12B, a center portion of the inner spacer material layer 254 between two opposing sidewalls of the gate spacers 226 receives the surface treatment, resulting in a material composition change, such that an etch selectivity exhibits compared to other parts of the inner spacer material layer 254. Then a selective etching process is applied in the cycle to remove the treated (e.g., oxidized or nitrified) surface portion of the inner spacer material layer 254, as the etching process that is tuned to be selective to oxide or nitride and does not substantially etch untreated portions. The remaining spaces (or voids) 252 facilitate the etchants to reach the treated surface portions at different locations and improves etching rate uniformity. The selective etching process may include wet etching, dry etching, reactive ion etching, or other suitable etching methods.

After removing the inner spacer material layer 254 from the channel region 212C, the channel members 2080 are released again. The spaces 252 are enlarged between the adjacent channel members 2080. As will be shown in further details below, a high-K metal gate (HK MG) structure is to form in the enlarged spaces 252, abutting the inner spacers 2540. The inner spacers 2540 therefore provides isolation between the metal gate structure and the epitaxial S/D features 238. A width of the enlarged spaces 252 measured in the X direction may be larger than a width between opposing sidewalls of the gate spacers 226. Accordingly, a lower portion of the to-be-formed metal gate structure under the topmost channel member 2080 may be wider measured in the X direction than its upper portion between the opposing sidewalls of the gate spacers 226. In the depicted embodiment as shown in FIGS. 12A and 12B, due to the etching process starting from the channel region 212C, the inner spacers 2540 has an inner sidewall facing the enlarged spaces 252, which exhibits a concave profile bending towards the source/drain features 244, and an outer sidewall interfacing the source/drain features 244, which is substantially straight.

In some embodiments of a GAA manufacturing flow, the etching process in forming the inner spacers starts from the source/drain regions 212SD, which leads to an outer sidewall having a concave profile bending towards the channel region 212C. As a comparison, the bending inner sidewall and substantially straight outer sidewall of the inner spacers 2540 as depicted herein represent one of the signature features of resultant devices through some exemplary manufacturing flow presented in the present disclosure. Notably, due to the curvature profile in the top surface of the topmost channel member 2080, a portion of the inner spacer material layer 254 in the corner region of the curvature profile may remain directly under the gate spacers 226 without being removed. The remaining portion of the inner spacer material layer 254 vertically stacked between the topmost channel member 2080 and the gate spacers 226 is denoted as dielectric residue 254R, which may remain in the final structure. The dielectric residue 254R that has the same material composition as the inner spacers 2540 as depicted herein represents another one of the signature features of resultant devices through some exemplary manufacturing flow presented in the present disclosure.

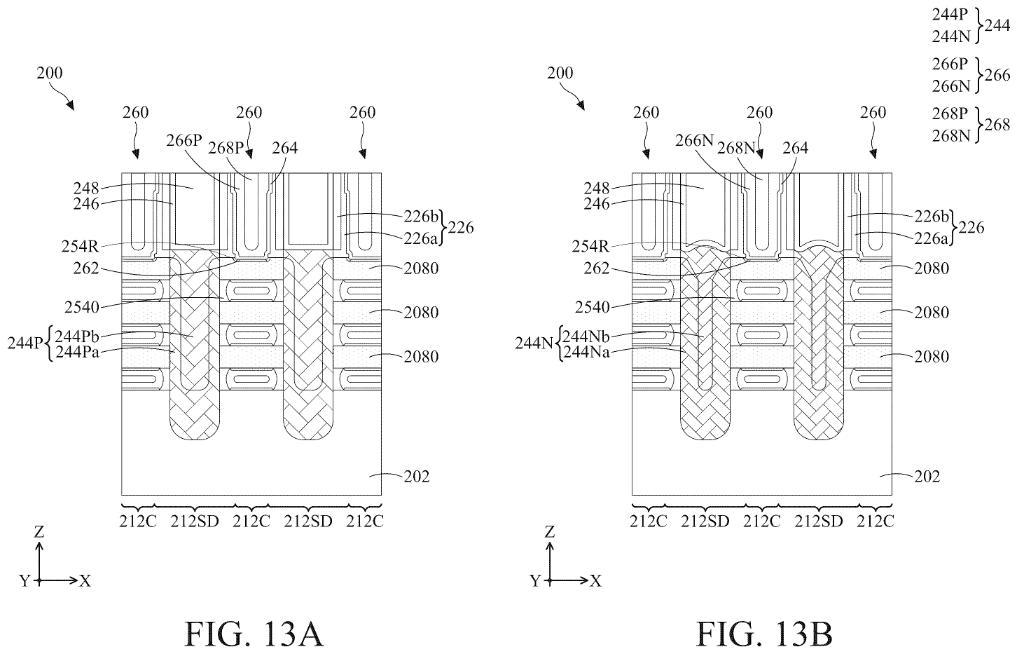

Referring to FIGS. 1 and 13A-B, method 100 includes a block 126 where gate structures 260 are formed in the gate trenches 250 to wrap around the channel members 2080. The gate structures 260 are also referred to as high-K metal gate (HK MG) structures due to the high-k dielectric layer and the metal-containing gate electrode layer, however other compositions are possible. As discussed above, a lower portion of the gate structure 260 under the topmost channel member 2080 may be wider measured in the X direction than its upper portion between the opposing sidewalls of the gate spacers 226 due to the enlarging of the spaces 252, as depicted in FIGS. 13A and 13B. Alternatively, the gate structure 260 may have a substantially uniform width in its upper and lower portions. In the depicted embodiment, the gate structure 260 includes an interfacial layer 262 interfacing the channel members 2080 and the substrate 202 in the channel region 212C, a high-K dielectric layer 264 over the interfacial layer 262, a work function layer 266 (including p-type work function layer 266P in the PFET region and n-type work function layer 266N in the NFET region) over the high-K dielectric layer 264, and a metal fill layer 268 (including metal fill layer 268P in the PFET region and metal fill layer 268N in the NFET region) surrounded by the work function layer 266. The interfacial layer 262 and the high-K dielectric layer 264 are collectively referred to as the gate dielectric layer. The work function layer 266 and the metal fill layer 268 are collectively referred to as the gate electrode layer.

The interfacial layer 262 may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K dielectric layer 264 may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTIO), combinations thereof, or other suitable material. The high-K dielectric layer 264 may be formed by ALD, physical vapor deposition (PVD), CVD, oxidation, and/or other suitable methods.

The work function layer 266 may be a p-type or an n-type work function layer depending on the type (PFET or NFET) of the device. The p-type work function layer 266P comprises a metal with a sufficiently large effective work function, selected from but not restricted to the group of titanium nitride (TiN), tantalum nitride (TaN), ruthenium (Ru), molybdenum (Mo), tungsten (W), platinum (Pt), or combinations thereof. The n-type work function layer 266N comprises a metal with sufficiently low effective work function, selected from but not restricted to the group of titanium (Ti), aluminum (Al), tantalum carbide (TaC), tantalum carbide nitride (TaCN), tantalum silicon nitride (TaSiN), titanium silicon nitride (TiSiN), or combinations thereof. Each of the metal fill layers 268N and 268P may include aluminum (Al), tungsten (W), cobalt (Co), and/or other suitable materials. In various embodiments, the gate electrode layer may be formed by ALD, PVD, CVD, e-beam evaporation, or other suitable process.

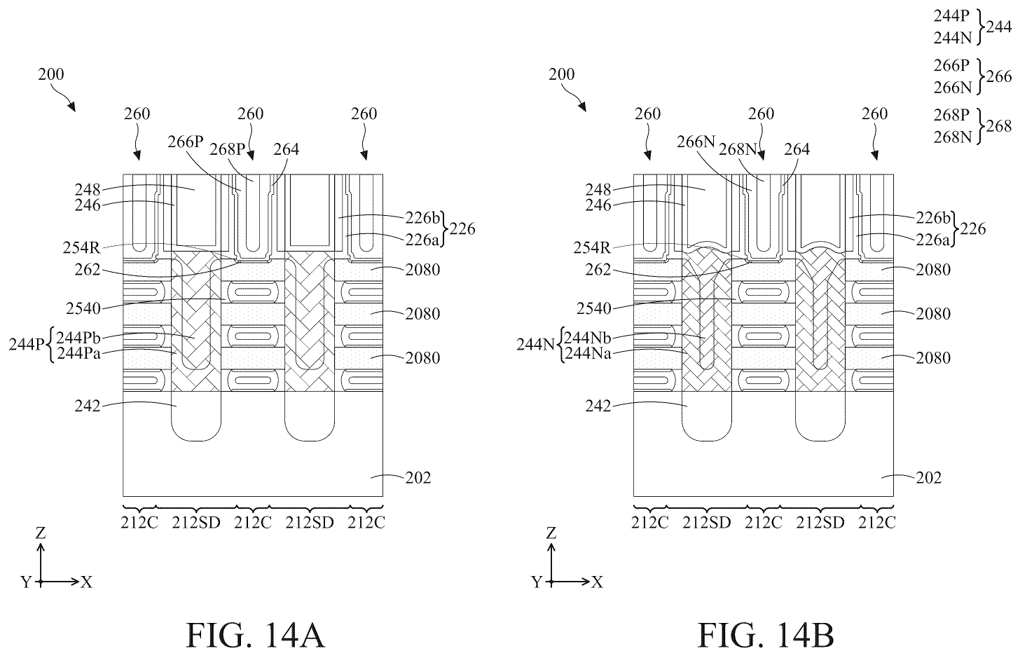

Reference is now made to FIGS. 14A and 14B. FIGS. 14A and 14B illustrate an alternative embodiment of the semiconductor device 200 at the conclusion of operations at block 126. The semiconductor device 200 as shown in FIGS. 14A and 14B has a lot of aspects similar to the embodiment as shown in FIGS. 13A and 13B. One difference is that a buffer epitaxial layer 242 is deposited under the bottom of the source/drain features 244. The buffer epitaxial layer 242 is epitaxially grown from the top surface of the fin-shaped base 212B prior to the forming of the source/drain features 244. By way of example, epitaxial growth of the buffer epitaxial layer 242 may be performed by VPE, ultra-high vacuum CVD (UHV-CVD), MBE, and/or other suitable epitaxial grow processes. In some embodiments, the buffer epitaxial layer 242 includes the same material as the substrate 202, such as silicon. In some alternative embodiments, the buffer epitaxial layer 242 includes a different semiconductor material other than silicon, such as SiGe, SiSn, or other suitable semiconductor material. In some embodiments, the buffer epitaxial layer 242 is dopant-free, where for example, no intentional doping is performed during the epitaxial growth process. As a comparison, in one instance, the substrate 202 is lightly doped and has a higher doping concentration than the buffer epitaxial layer 242. The buffer epitaxial layer 242 provides a high resistance path from the S/D regions to the semiconductor substrate, such that the leakage current in the semiconductor substrate is suppressed.

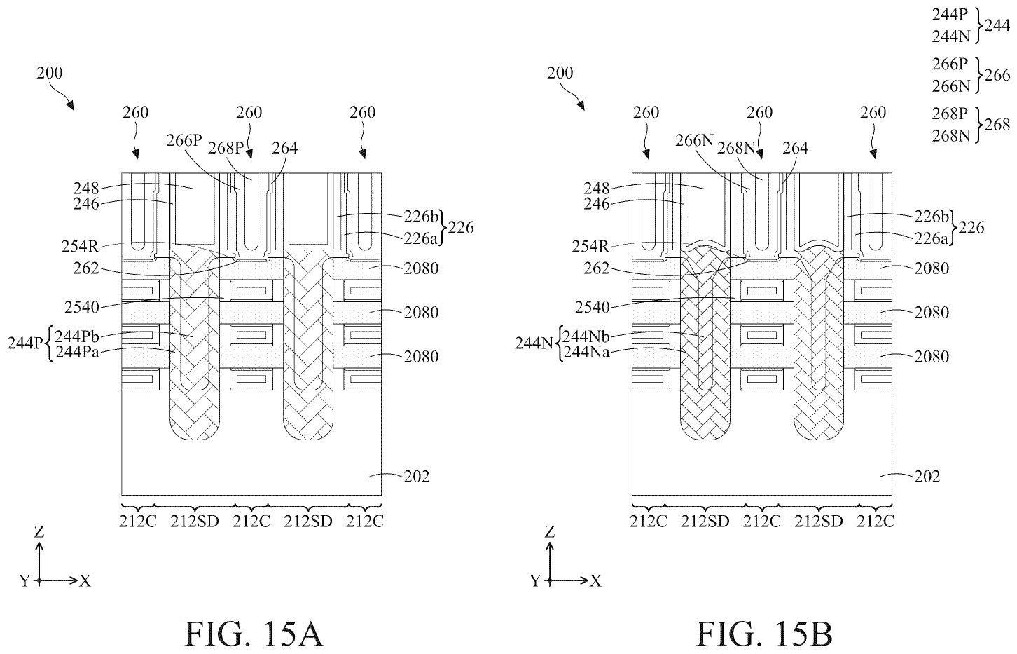

Reference is now made to FIGS. 15A and 15B. FIGS. 15A and 15B illustrate an alternative embodiment of the semiconductor device 200 at the conclusion of operations at block 126. The semiconductor device 200 as shown in FIGS. 15A and 15B has a lot of aspects similar to the embodiment as shown in FIGS. 13A and 13B. One difference is that the inner spacers 2540 have more of a rectangular shape with both inner and outer sidewalls substantially straight. The straight inner sidewalls are mainly due to different parameters applied to the cyclic etching process at block 124.

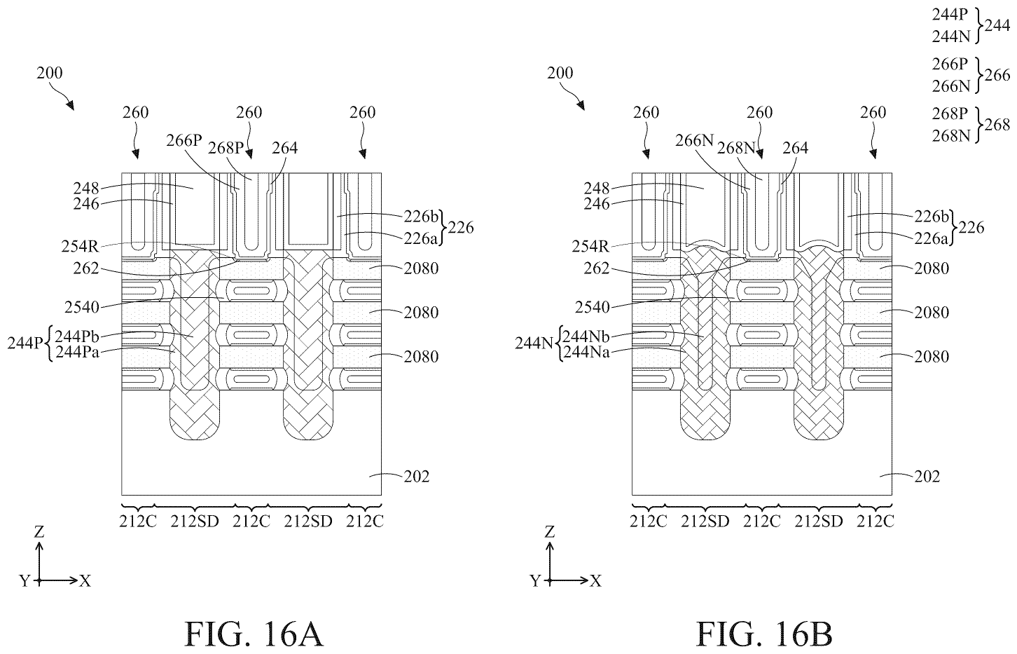

Reference is now made to FIGS. 16A and 16B. FIGS. 16A and 16B illustrate an alternative embodiment of the semiconductor device 200 at the conclusion of operations at block 126. The semiconductor device 200 as shown in FIGS. 16A and 16B has a lot of aspects similar to the embodiment as shown in FIGS. 13A and 13B. One difference is that the inner spacers 2540 have both inner and outer sidewalls having curvature profiles bending towards the source/drain features 244. Due to the curvature outer sidewalls, a portion of the inner spacers 2540 is partially embedded into the sidewall of the source/drain features 244. The curvature outer sidewalls are mainly due to etching loss occurred to the outer layer of the source/drain features 244 due to limited etching contrast during the selective removal of the sacrificial layers 206 at block 120.

The semiconductor device 200 may undergo further processing to form various features and regions known in the art. For example, subsequent processing may form contact openings, contact metal, as well as various contacts/vias/lines and multilayers interconnect features (e.g., metal layers and interlayer dielectrics) on the substrate 202, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

Although not intended to be limiting, embodiments of the present disclosure provide one or more of the following advantages. For example, embodiments of the present disclosure provide an inner spacer formation method after the formation of source/drain features, which effectively reduces crystalline dislocation and other defects in source/drain regions of GAA transistors. Furthermore, the inner spacer formation method can be easily integrated into existing semiconductor fabrication processes.

In one exemplary aspect, the present disclosure is directed to a method. The method includes forming over a substrate a stack that includes a plurality of channel layers interleaved by a plurality of sacrificial layers, patterning the stack to form a fin-shaped structure, forming a dummy gate stack over a channel region of the fin-shaped structure, depositing gate spacers on sidewalls of the dummy gate stack, recessing a source/drain region of the fin-shaped structure to form a source/drain trench, the source/drain trench exposing sidewalls of the channel layers and sidewalls of the sacrificial layers, epitaxially growing a first epitaxial layer from the sidewalls of the channel layers and the sidewalls of the sacrificial layers, epitaxially growing a second epitaxial layer on the first epitaxial layer, removing the dummy gate stack, selectively removing the sacrificial layers in the channel region to release the channel layers as channel members, depositing a dielectric material layer wrapping around the channel members, removing the dielectric material layer from the channel region, while a portion of the dielectric material layer directly under the gate spacers remains as inner spacers, and forming a metal gate structure wrapping around the channel members, the inner spacers interposing the metal gate structure and the first epitaxial layer. In some embodiments, the inner spacers have a first sidewall interfacing the first epitaxial layer and a second sidewall interfacing the metal gate structure, and the second sidewall of the inner spacers bends towards the first epitaxial layer. In some embodiments, the first sidewall of the inner spacers is substantially straight. In some embodiments, the first sidewall of the inner spacers bends towards the first epitaxial layer. In some embodiments, the depositing of the dielectric material layer includes a cyclic deposition and etching process. In some embodiments, the removing of the dielectric material layer includes a cyclic surface treatment and etching process. In some embodiments, after the depositing of the dielectric material layer, voids remain between adjacent ones of the channel members. In some embodiments, the first epitaxial layer and the second epitaxial layer each include silicon germanium, and a germanium concentration in atomic percentage in the first epitaxial layer is smaller than in the second epitaxial layer. In some embodiments, the first epitaxial layer includes a first sidewall interfacing the channel members and a second sidewall interfacing the second epitaxial layer, and the first and second sidewalls of the first epitaxial layer are substantially straight. In some embodiments, the method further includes forming an epitaxial buffer layer between the substrate and the first epitaxial layer.

In another exemplary aspect, the present disclosure is directed to a method. The method includes forming a structure including multiple channel members vertically stacked above a substrate, forming a source/drain feature abutting the channel members, after the forming of the source/drain feature, depositing a dielectric material layer wrapping around the channel members, voids remaining between adjacent ones of the channel members after the deposition of the dielectric material layer, selectively removing a center portion of the dielectric material layer to release the channel members, and forming a metal gate structure wrapping around the channel members. A side portion of the dielectric material layer interposes the metal gate structure and the source/drain feature. In some embodiments, the selectively removing of the center portion of the dielectric material layer includes repeating steps of performing a treatment process and a selective etching process until the channel members are released. In some embodiments, the treatment process is an oxidation process or a nitridation process. In some embodiments, the side portion of the dielectric material layer includes a first sidewall facing the source/drain feature and a second sidewall facing the metal gate structure, and wherein the second sidewall of the side portion of the dielectric material layer bends towards the source/drain feature. In some embodiments, the first sidewall of the side portion of the dielectric material layer is substantially straight. In some embodiments, after the selectively removing of the center portion of the dielectric material layer, a portion of the dielectric material layer remains on a top surface of a topmost one of the channel members.

In yet another exemplary aspect, the present disclosure is directed to a semiconductor structure. The semiconductor structure includes a plurality of nanostructures suspended above a substrate, a gate structure wrapping around each of the plurality of nanostructures, a gate spacer disposed on a sidewall of the gate structure, a source/drain feature abutting the nanostructures, and an inner spacer interposed between the gate structure and the source/drain feature and extending between two adjacent ones of the nanostructures. The inner spacer includes a first sidewall facing the source/drain feature and a second sidewall facing the gate structure, the first sidewall is straight and vertical, and the second sidewall bends towards the source/drain feature. In some embodiments, the gate structure includes a lower portion under a topmost one of the nanostructures and an upper portion above the topmost one of the nanostructures, and the lower portion is wider than the upper portion measured in a lengthwise direction of the nanostructures. In some embodiments, the source/drain feature includes a first epitaxial layer and a second epitaxial layer surrounded by the first epitaxial layer, the first epitaxial layer includes a sidewall facing the gate structure, and the sidewall of the first epitaxial layer is straight and vertical. In some embodiments, the first epitaxial layer includes a germanium concentration lower than that of the second epitaxial layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming over a substrate a stack that includes a plurality of channel layers interleaved by a plurality of sacrificial layers;
patterning the stack to form a fin-shaped structure;
forming a dummy gate stack over a channel region of the fin-shaped structure;
depositing gate spacers on sidewalls of the dummy gate stack;
recessing a source/drain region of the fin-shaped structure to form a source/drain trench, the source/drain trench exposing sidewalls of the channel layers and sidewalls of the sacrificial layers;
epitaxially growing a first epitaxial layer from the sidewalls of the channel layers and the sidewalls of the sacrificial layers;
epitaxially growing a second epitaxial layer on the first epitaxial layer;
removing the dummy gate stack;
selectively removing the sacrificial layers in the channel region to release the channel layers as channel members;
depositing a dielectric material layer wrapping around the channel members;
removing the dielectric material layer from the channel region, while a portion of the dielectric material layer directly under the gate spacers remains as inner spacers; and
forming a metal gate structure wrapping around the channel members, the inner spacers interposing the metal gate structure and the first epitaxial layer.

2. The method of claim 1, wherein the inner spacers have a first sidewall interfacing the first epitaxial layer and a second sidewall interfacing the metal gate structure, and wherein the second sidewall of the inner spacers bends towards the first epitaxial layer.

3. The method of claim 2, wherein the first sidewall of the inner spacers is substantially straight.

4. The method of claim 2, wherein the first sidewall of the inner spacers bends towards the first epitaxial layer.

5. The method of claim 1, wherein the depositing of the dielectric material layer includes a cyclic deposition and etching process.

6. The method of claim 1, wherein the removing of the dielectric material layer includes a cyclic surface treatment and etching process.

7. The method of claim 1, wherein, after the depositing of the dielectric material layer, voids remain between adjacent ones of the channel members.

8. The method of claim 1, wherein the first epitaxial layer and the second epitaxial layer each include silicon germanium, and wherein a germanium concentration in atomic percentage in the first epitaxial layer is smaller than in the second epitaxial layer.

9. The method of claim 1, wherein the first epitaxial layer includes a first sidewall interfacing the channel members and a second sidewall interfacing the second epitaxial layer, and wherein the first and second sidewalls of the first epitaxial layer are substantially straight.

10. The method of claim 1, further comprising:
forming an epitaxial buffer layer between the substrate and the first epitaxial layer.

11. A method, comprising:
forming a structure including multiple channel members vertically stacked above a substrate;
forming a source/drain feature abutting the channel members;
after the forming of the source/drain feature, depositing a dielectric material layer wrapping around the channel members, wherein voids remain between adjacent ones of the channel members after the deposition of the dielectric material layer;
selectively removing a center portion of the dielectric material layer to release the channel members; and
forming a metal gate structure wrapping around the channel members, wherein a side portion of the dielectric material layer interposes the metal gate structure and the source/drain feature.

12. The method of claim 11, wherein the selectively removing of the center portion of the dielectric material layer includes repeating steps of performing a treatment process and a selective etching process until the channel members are released.

13. The method of claim 12, wherein the treatment process is an oxidation process or a nitridation process.

14. The method of claim 11, wherein the side portion of the dielectric material layer includes a first sidewall facing the source/drain feature and a second sidewall facing the metal gate structure, and wherein the second sidewall of the side portion of the dielectric material layer bends towards the source/drain feature.

15. The method of claim 14, wherein the first sidewall of the side portion of the dielectric material layer is substantially straight.

16. The method of claim 11, wherein, after the selectively removing of the center portion of the dielectric material layer, a portion of the dielectric material layer remains on a top surface of a topmost one of the channel members.

17. A semiconductor structure, comprising:
a plurality of nanostructures suspended above a substrate;
a gate structure wrapping around each of the plurality of nanostructures;
a gate spacer disposed on a sidewall of the gate structure;
a source/drain feature abutting the nanostructures; and
an inner spacer interposed between the gate structure and the source/drain feature and extending between two adjacent ones of the nanostructures, wherein the inner spacer includes a first sidewall facing the source/drain feature and a second sidewall facing the gate structure, the first sidewall is straight and vertical, and the second sidewall bends towards the source/drain feature.

18. The semiconductor structure of claim 17, wherein the gate structure includes a lower portion under a topmost one of the nanostructures and an upper portion above the topmost one of the nanostructures, and the lower portion is wider than the upper portion measured in a lengthwise direction of the nanostructures.

19. The semiconductor structure of claim 17, wherein the source/drain feature includes a first epitaxial layer and a second epitaxial layer surrounded by the first epitaxial layer, the first epitaxial layer includes a sidewall facing the gate structure, and the sidewall of the first epitaxial layer is straight and vertical.

20. The semiconductor structure of claim 19, wherein the first epitaxial layer includes a germanium concentration lower than that of the second epitaxial layer.
